(19) United States
(12) Patent Application Publication
(10) Pub. No.: US 2001/0055883 A1
(43) Pub. Date: Dec. 27, 2001

(54) Method of producing a semiconductor device having tapered through holes

(76) Inventor: Takayuki Kawazoe, Tokyo (JP)

Correspondence Address: Darryl G. Walker, WALKER & SAKO, LLP, Suite 235, 300 South First Street, San Jose, CA, 95113, US

(21) Appl. No.: 09/879,429

(22) Filed: Jun. 12, 2001

(30) Foreign Application Priority Data
Jun. 13, 2000 (JP) 2000-177411

(51) Int. Cl. H01L 21/311

(52) U.S. Cl. 438/700

(57) ABSTRACT

A method of producing a semiconductor device having a tapered through hole without wet etching or masking with polysilicon is disclosed. The method may include forming an interlayer insulating film (2) and first insulating film (7) over a lower wiring layer (1). With a photoresist layer (3) as a mask, dry etching may form a recess (8) in the surface of interlayer insulating film (2). After removing photoresist (3), a second insulating film (9) may be formed over first insulating film (7) and within recess (8). Second insulating film (9) may be etched back to form a sidewall (9a) within recess (8). A through hole (10) may then be formed by etching under conditions that result in an etch speed ratio between an interlayer insulating film (2) and sidewall (9a) in the range of about 10. A through hole (10) can thus be formed having a tapered shape and desired slope.

### TECHNICAL FIELD

The present invention relates to a method of producing semiconductor devices having tapered through holes, and more particularly to a method of producing semiconductor devices with satisfactory wiring material coverage within such tapered through holes.

### BACKGROUND OF THE INVENTION

One of the factors that can decrease the reliability of semiconductor devices is electromigration within through holes that connect an upper wiring layer with a lower wiring layer. One way to address the adverse effects of electromigration can be to try to improve coverage of wiring materials within through holes. One approach to improving wiring material coverage is to decrease the aspect ratio of through holes. Aspect ratio of a through hole may be increased by forming through holes with a tapered shape. Such tapered through holes can include a top hole opening having a larger area than a bottom hole opening.

Various prior art approaches for forming through holes will now be described.

Numerous methods for forming cylindrical through holes have been proposed in the prior art. A cylindrical through hole can include a top hole opening having an area that is essentially the same as a bottom hole opening. One example is shown in Japanese Patent No. 2505359, which discloses an insulating film formed on a silicon substrate. A recess is formed in the insulating film, and a sidewall formed from polysilicon is formed in the inside wall of the recess. A contact hole is formed by etching with the sidewall as an etch mask. According to this method, a contact hole having a nearly cylindrical shape can be formed. Such a contact hole may have an opening equal to or less than the resolution of an exposure device. Further, such a method may form such holes with good reproducibility.

In the method of Japanese Patent No. 2505359, a polysilicon sidewall material is used which has a high etch selectivity with respect to an oxide. This can achieve the object of forming a contact hole with a size equal to or less than the resolution of an exposure device. However, such a contact hole has a top hole opening with an area that is essentially the same as a bottom hole opening. That is, it appears the above approach does not form a tapered shape. As noted above, without a tapered shape, coverage of a wiring layer may be inferior.

Yet another drawback to the method shown in Japanese Patent No. 2505359 can be high temperature processes. In particular, polysilicon (used to form a sidewall) is typically deposited by lower pressure chemical vapor deposition (CVD) at a temperature equal to or higher than the melting point of aluminum. Thus, if aluminum is used as a lower wiring layer, polysilicon most likely cannot be used as a material for forming a through hole.

In addition to various cylindrical contact hole approaches, several technologies have been proposed in which the upper portion of a through hole may be tapered, while a lower portion is cylindrical. FIG. 3 shows one example of a method for forming a through hole with such a shape.

In the example of FIG. 3, an interlayer insulating film 2 is formed on a lower wiring layer 1. A mask 3 is then formed over the interlayer insulating film 2 from photoresist. A mask 3 includes an opening at the desired location of a contact hole. With mask 3 in place, an upper portion of the interlayer insulating film 2 is wet etched forming a recess with a tapered side 4. A lower portion of the interlayer insulating film 2 may be dry etched forming a lower portion of a through hole having a cylindrical side 5.

Another method is disclosed in Japanese Unexamined Patent Application No. 10-289951. In this method, after forming a semiconductor element on a semiconductor substrate, an interlayer insulating film is formed and a contact hole is formed in the interlayer insulating film. More particularly, a recess is formed in the area where a through hole is desired. An insulating film may then be formed on the side walls of the recess. The insulating film has a high etch selectivity ratio relative to the interlayer insulating film. By using the insulating film as an etch stop, a through hole may be formed having an upper portion with a tapered shape and a lower portion with a cylindrical shape. The above method is believed to ensure a sufficient insulating margin is maintained between a semiconductor element and the sides of a through hole. In addition, the surface area for the bottom of the contact hole is believed to be improved, adding to the reliability of the semiconductor device.

In the latter two examples, while an upper portion of a through hole has a tapered shape, the lower portion has a cylindrical shape. Such a cylindrical shape may suffer from inadequate coverage of a wiring layer. It is noted that a primary objective of Japanese Unexamined Patent Application No. 10-289951 was believed to be the prevention of shorting between a semiconductor element formed on a substrate, and a side wall of a contact hole. Such a contact hole therefore retains a tapered upper portion and cylindrical lower portion, which can prevent adequate wiring layer coverage.

Another method is shown in Japanese Unexamined Patent Application No. 3-257822 which expands on the method shown in FIG. 3 by forming a through hole with a slope extending from the bottom opening to the top opening. FIGS. 4A, 4B, 5A and 5B are side cross sectional views showing this method.

As shown in FIG. 4A, an interlayer insulating film 2 is formed on a lower wiring layer 1. Photoresist 3, having an opening, is then formed over the interlayer insulating film 2. An upper portion of the interlayer insulating film 2 is wet etched to form a recess 4. Photoresist 3 is then removed. As shown in FIG. 4B, another insulating film 6 is formed over interlayer insulating film 2, including within recess 4. The other insulating film 2 is then etched.

As shown in FIG. SA, following the etching of the other insulating film 2, insulating film 6 remains on the side walls of recess 4. The entire structure may then be etched back, forming a hole with a gentle slope without any projecting portions. Such a hole is shown in FIG. 5B.

An approach, such as that shown in FIGS. 4A, 4B, SA and 5B is not believed to be without drawbacks. As noted, such a method forms an insulating film 6 on the sidewall of a recess 4 formed by wet etching. A subsequent etch back of the entire structure can form a contact hole with a smooth slope that is free of unwanted projections. However, such an approach can form a contact hole with an opening that is large relative to the height of the contact hole. For example, to reduce wiring gaps, it is desirable to increase the thickness of an interlayer insulating film. But a thicker interlayer insulating film may require an increase in the size of a recess 4. Consequently, forming such a contact hole in a thicker interlayer insulating film can produce an overly large contact hole opening. Such larger openings can inhibit higher integration of a semiconductor device.

Thus, as illustrated in the above examples, it has been difficult in conventional approaches to control the slope and/or opening size of a through hole and arrive at an optimal shape.

It is further noted that conventional approaches may not integrate with some modem materials. In particular, thick film inorganic silica is more frequently used as a planarizing material for interlayer insulating film. The use of thick film inorganic silica can dispense with the need for an etchback step. However, because no etchback step occurs, a thick film inorganic silica can be formed over an entire substrate, including regions where a contact hole is to be formed. Unfortunately, thick film inorganic silica may have drawbacks if utilized in the above-mentioned methods.

First, the wet etching rate of thick film inorganic silica can be several times that of thermal or plasma oxide films. Thus, it may be difficult to employ a wet etch in decreasing aspect ratio of through holes. Second, thick film inorganic silica can be highly hygroscopic. Thus, because most wet etches include water, wet etching thick film inorganic silica can decrease the reliability of such a film.

While hole shapes may improve wiring layer coverage within a hole, other approaches may also improve coverage. For example, high temperature sputtering can improve wiring layer coverage. In high temperature sputtering, a film is deposited by sputtering a wiring material at a temperature equal to or greater than the melting point of the wiring material. More particularly, by depositing aluminum with high temperature sputtering, a contact hole may be filled with aluminum that has improved coverage over other deposition approaches.

However, despite the advantages that high temperature sputtering provides, it is still important to decrease the aspect ratio (i.e., provide a slope or tapered shape) in a through hole, to thereby improve the coverage of a wiring layer.

### SUMMARY OF THE INVENTION

An object of the present invention is to provide a method of producing semiconductor devices that forms through holes having a tapered shape without necessarily wet etching or including polysilicon as an etch mask. Such a tapered through hole may provide for improved wiring material coverage than through holes having cylindrical shapes or portions.

According to one embodiment, a method of forming tapered through holes may include forming an interlayer insulating film on a lower wiring layer. A first insulating film (e.g., plasma nitride) may be formed over the interlayer insulating film. An opening can be formed in the first insulating film. A recess may be formed in the interlayer insulating film, below the opening, that includes second insulating film (e.g., plasma nitride) sidewalls formed in recess inner walls. The recess may then be dry etched, where an etch speed ratio between the interlayer insulating film and second insulating film is in the range of about 5 to 15.

According to the disclosed embodiments, the slope of through hole taper may be optimal when etching is performed according to the above disclosed ratio range of 5 to 15. It is believed that etch speed ratios greater than 15 may produce through holes having shapes approaching cylindrical. This may result in decreased wiring material coverage within a through hole. Etch speed ratios less than 5 may produce through holes having undesirably large top openings. This may inhibit higher integration of a semiconductor device.

According to one aspect of the embodiments, a method may further include forming a layer photoresist over the first insulating film that includes an opening. An opening in the first insulating film and a recess in the interlayer insulating film may then be formed by dry etching with the photoresist as an etch mask. The photoresist may then be removed and the second insulating film may be formed over the first insulating film and in the recess. The second insulating film may then be etched back to form sidewalls.

If a second film is formed from plasma nitride, a sidewall may be formed at a lower temperature than that used to from polysilicon. This can enable a lower wiring layer to be formed from a material with a lower melting point, such as aluminum. In this way, unlike may other conventional approaches tapered through holes may be formed to a lower melting point wiring layer.

It is further noted that if a second film is formed from plasma nitride, such plasma nitride may have a smaller etch rate ratio relative to an oxide film than a polysilicon. This can enable an etch rate ratio between an interlayer insulating film of oxide and a sidewall film of nitride to be in the desirable range of about 5 to 15.

Finally, it is noted that a plasma nitride as used in the present invention refers to a film that has been nitrided by a plasma nitride species. One common plasma nitride includes silicon nitride.

### BRIEF DESCRIPTION OF THE DRAWINGS

FIGS. 1A and 1B are side cross sectional view of a through hole forming method according to one embodiment.

FIGS. 2A, 2B, and 2C are side cross sectional view of a through hole forming method according to one embodiment.

FIG. 3 is a side cross sectional view of a conventional through hole forming method.

FIGS. 4A and 4B are side cross sectional view of another conventional through hole forming method.

FIGS. 5A and 5B are side cross sectional view of the other conventional through hole forming method.

### DETAILED DESCRIPTION OF THE EMBODIMENTS

Various embodiments of the present invention will now be described in detail with reference to a number of drawings.

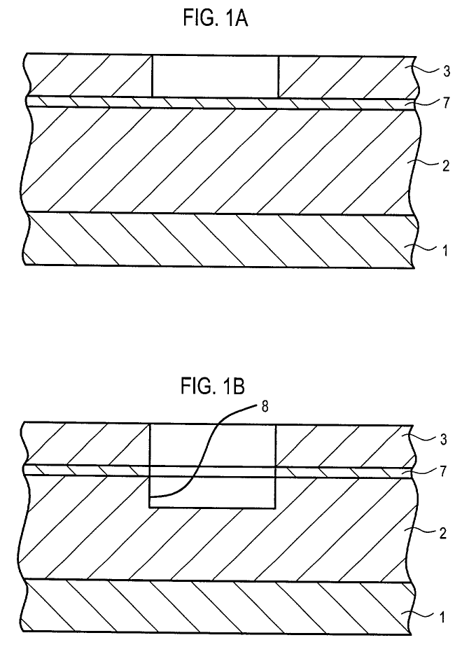

FIGS. 1A, 1 B, 2A, 2B, and 2C are side cross sectional views illustrating various steps in a method of forming a semiconductor device according to one embodiment. The particular example shown can be included in the production of a dynamic random access memory (DRAM). In such an application, a transistor, such as a metal-oxide-semiconductor field effect transistor (MOSFET) and corresponding storage capacitor may be formed on a semiconductor substrate. A lower wiring layer 1 may then be formed on a lower interlayer insulating film (not shown). A lower wiring layer 1 may comprise various conductive materials including but not limited to titanium (Ti), titanium nitride (TiN), aluminum-copper (Al-Cu), etc.

An interlayer insulating film 2 may then be formed on a lower wiring layer 1. An interlayer insulating film 2 may comprise a plasma oxide, as but one example. A first insulating film 7 may then be formed over interlayer insulating film 2. First insulating film 7 may have a slower etch rate than interlayer insulating film 2 during certain etching steps. If an interlayer insulating film 2 comprises a plasma oxide, first insulating film 7 may comprise a plasma nitride.

Referring still to FIG. 1A, a coating of photoresist 3 may be formed over first insulating film 7. A portion of photoresist 3 may then be removed to form an opening at the desired location of a through hole. Such a selective removal of photoresist 3 may be accomplished with photolithographic technology.

Referring now to FIG. 1B, an insulating film 7 may be removed using photoresist 3 as a mask. Further, an upper portion of interlayer insulating film 2 may also be removed to form a recess 8 in a surface of the interlayer insulating film 2. In one particular approach, portions of first insulating film 7 may be removed and/or a recess 8 may be formed by dry etching. Photoresist 3 may then be removed.

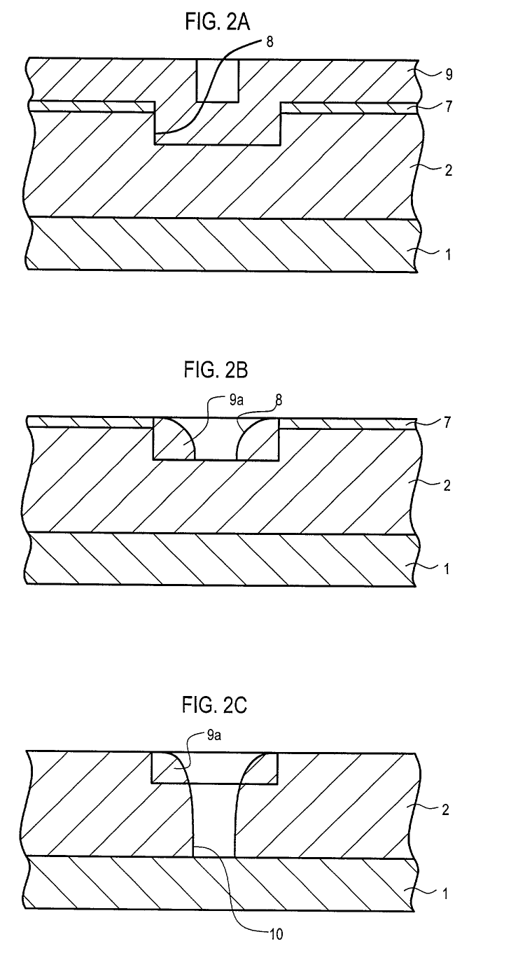

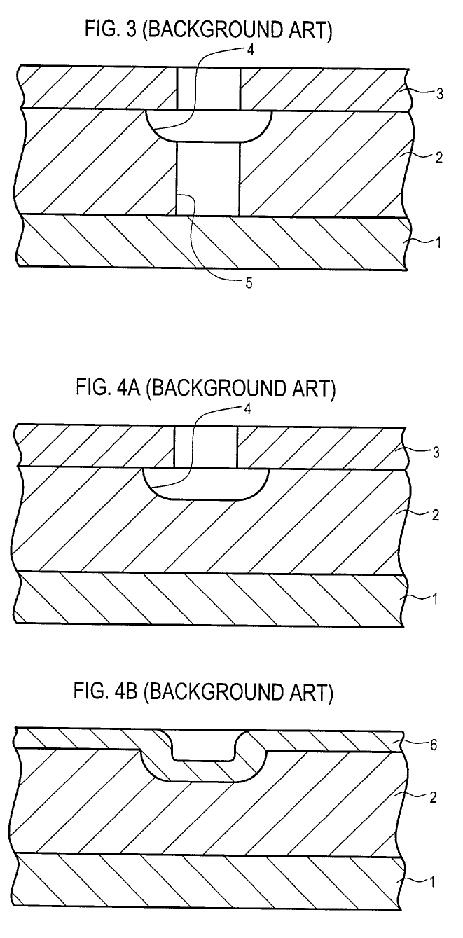

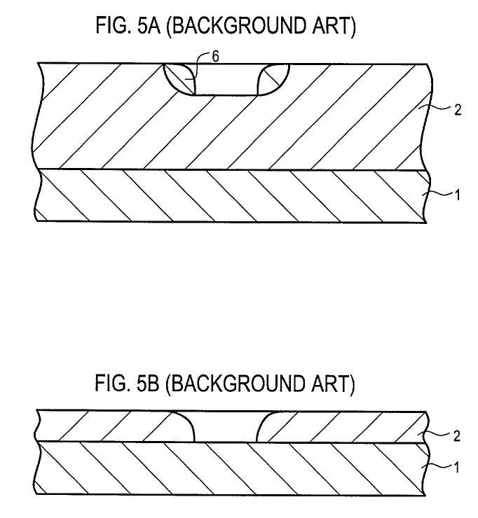

Referring now to FIG. 2A, after removing photoresist 3, a second insulating film 9 may be formed over first insulating film 7 and within recess 8. Like first insulating film 7, second insulating film 9 may have a slower etch rate than interlayer insulating film 2 during certain etching steps. As one example, if an interlayer insulating film 2 comprises a plasma oxide and first insulating film 7 comprises a plasma nitride, second insulating film 9 may also comprise a plasma nitride.

Referring now to FIG. 2B, a second insulating film 9 may be etched back resulting in the formation of sidewall 9a on a sidewall of recess 8. First insulating film 7 may remain over interlayer insulating film 2.

An entire substrate may then be etched. Such an etching may occur with a differential etch rate between interlayer insulating film 2 and first insulating film 7 and remaining sidewall 9a of second insulating film 9. In one particular approach, an interlayer insulating film 2 may be etched approximately 10 times faster than first insulating film 7 and remaining sidewall 9a. Even more particularly, such an etching may be a dry etch with an etching gas that includes C₄F₈, Ar and O₂.

Such an above-described etching step can result in an interlayer insulating film 2 being etched away at a relatively fast rate, while the remaining sidewall 9a is etched away at a relatively slower rate. Consequently, a contact hole depth may increase relatively rapidly, while a contact hole diameter increases more gradually. A resulting through hole example is shown in FIG. 2C. A sidewall 9a (or portion thereof) can remain, while a through hole 10 extends through interlayer insulating film 2 exposing lower wiring layer 1. In this manner, a through hole 10 having a sloping side wall can be formed.

According to the embodiment shown above, a dry etching step may have an etching speed ratio between an interlayer insulating film 2 and a sidewall 9a that is about 10. This can provide a relatively easy way to form a through hole having a sidewall surface with a desired incline between a top opening and a bottom opening. As a result, even if an interlayer insulating film 2 is relatively thick, wiring material coverage within such a hole may be improved over conventional approaches, without having to increase the size of a through hole top opening. This may help to suppress electromigration and therefore improve the reliability of a semiconductor device.

It is also noted that while the above examples have indicated that an interlayer insulating film 2 may comprise a plasma oxide, alternate materials may be included that are not always compatible with conventional approaches. In particular, because a through hole etching step can be a dry etch, a hygroscopic material such as inorganic silica can be included in an interlayer insulating film without the drawbacks inherent in conventional methods that may use a wet etch.

Still further, according to the embodiments shown, a sidewall material may be formed at a lower temperature than other conventional approaches. In particular, conventional approaches described may include polysilicon as a sidewall material, which may require process temperature that is higher than the melting point of aluminum. In contrast, according to the present invention, a sidewall material may comprise plasma nitride, which may be formed at a lower temperature, enabling aluminum to be included in a lower wiring layer 1.

Of course, while particular etch rate differences have been described, such rates should not necessarily limit the invention thereto. In particular, embodiments have been described in which the ratio of dry etching speed between an interlayer insulating film 2 and a sidewall 9a may be about 10. However, other suitable ratios may be in the general range of about 5 to 15. It is believed that etching rate differences in this general range can yield through holes with sidewalls of acceptable slope, even for interlayer insulating films that are relatively thick. Such a slope can provide for satisfactory wiring layer coverage within a through hole, as noted above. Further, etching within such ranges may form through holes without unwanted increases in the size of a through hole top opening.

Still further, while a through hole forming etch step may maintain particular etching conditions for the entire etch, such conditions may be changed part way through the etching step. Such an approach can enable a through hole slope to be varied at one or more points along a through hole side wall.

As has been described in detail, according to an embodiment, a method of producing a semiconductor device may include forming a through hole having a tapered shape in which side walls of a through hole have a desired incline between a through hole top opening and bottom opening. Such an incline can improve a wiring layer coverage within a through hole, thereby inhibiting the adverse effects of electromigration within a through hole. This can improve reliability of a semiconductor device.

Various other advantages may be realized by the invention. Because embodiments are shown that do not include wet etching, a semiconductor device may include hygroscopic materials, such thick film inorganic silica in an interlayer insulating film. Moreover, since polysilicon is not used to mask an interlayer insulating film, a lower melting point material, such as aluminum, may be included in a lower wiring layer. In this way, methods according to the present invention may provide greater degrees of freedom in the manufacture of semiconductor devices than conventional approaches.

While the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A method of producing a semiconductor device, comprising the steps of:
forming an interlayer insulating film over a lower wiring layer;
forming a first insulating film over the interlayer insulating film;
forming an opening in the first insulating film at a through hole location;
forming a recess in the interlayer insulating film below the opening in the first insulating film;
forming a sidewall on sides of the recess comprising a second insulating film; and
etching the interlayer insulating film with the first insulating film and sidewall as a mask, the etching including an etch rate ratio between the interlayer insulating film and the first and second insulating films that is in the general range of 5 to 15.

2. The method of claim 1, wherein:
the first insulating film comprises plasma nitride.

3. The method of claim 1, wherein:
the second insulating film comprises plasma nitride.

4. The method of claim 1, wherein:
the etching the interlayer insulating film is a dry etch.

5. The method of claim 1, wherein:
the step of forming an opening in the first insulating film at a through hole location and forming a recess in the interlayer insulating film includes
forming a photoresist layer over the first insulating film that has an opening at the through hole location, and
etching through the first insulating layer and into the interlayer insulating film to form the recess.

6. The method of claim 5, wherein:
etching through the first insulating layer and into the interlayer insulating film includes dry etching.

7. The method of claim 1, wherein:
forming a sidewall on sides of the recess includes
forming the second insulating film over the first insulating film and in the recess, and
etching back the second insulating film to form the sidewall.

8. The method of claim 1, wherein:
the e interlayer insulating film comprises thick film inorganic silica.

9. The method of claim 1, wherein:
the interlayer insulating film comprises plasma silicon oxide.

10. The method of claim 1, wherein:
the lower wiring layer comprises aluminum.

11. A method of producing a semiconductor device through hole, comprising the steps of:
forming an interlayer insulating film that is covered with a first insulating film and exposed in a recess formed in the top surface of the interlayer insulating film, the recess including a side wall covered with a second insulating film sidewall; and
etching the interlayer insulating film between about 5-15 times faster than the first and second insulating films.

12. The method of claim 11, wherein:
etching the interlayer insulating film includes dry etching with a fluorocarbon etching gas.

13. The method of claim 12, wherein:
the etching gas comprises C₄F₈, Ar and O₂.

14. The method of claim 11, wherein:
etching the interlayer insulating film includes etching the interlayer insulating film between about 7-12 times faster than the first and second insulating films.

15. The method of claim 14, wherein:
etching the interlayer insulating film includes etching the interlayer insulating film about 10 times faster than the first and second insulating films.

16. A method semiconductor device producing method, comprising the steps of:
forming an interlayer insulating film over a lower wiring layer;
forming a first insulating layer over the interlayer insulating film;
etching through the first insulating film into the interlayer insulating film to form a recess;
forming a second insulating film over the first insulating film and in the recess;
etching back the second insulating film to form a second insulating film sidewall in the recess; and
etching the interlayer insulating film with the second insulating film sidewall and first insulating film as an etch mask.

17. The method of claim 16, wherein:
etching the interlayer insulating film includes etching the interlayer insulating film about 5-15 times faster than the first and second insulating films.

18. The method of claim 16, wherein:
the first and second insulating films comprise nitride.

19. The method of claim 16, wherein:
the interlayer insulating film comprises silicon oxide.

20. The method of claim 16, wherein:
the interlayer insulating film comprises inorganic silica.
